(19) United States
(12) Patent Application Publication
(10) Pub. No.: US 2011/0114383 A1
(43) Pub. Date: May 19, 2011

(54) POTTED ELECTRONIC COMPONENT AND METHOD FOR ITS MANUFACTURE

(75) Inventor: Robertus W. Covers, Swartz Creek, MI (US)

(73) Assignee: DELPHI TECHNOLOGIES, INC., Troy, MI (US)

(21) Appl. No.: 12/617,752

(22) Filed: Nov. 13, 2009

(51) Int. Cl. H01L 23/28; B29C 70/70

(52) U.S. Cl. 174/521; 264/272.11

(57) ABSTRACT

A method of manufacturing an electronic component assembly is disclosed comprising disposing an electronic component in a housing such that there is at least one void space between the component and the housing, disposing non-conductive microspheres in the void space to substantially fill the void space, and disposing a fluid potting material in the housing and hardening or curing the potting material to pot the component in the housing. An assembly is also disclosed comprising a housing, an electronic component disposed in the housing such that there is at least one space between the component and the housing and the space is substantially filled with non-conductive microspheres, and a material that potting the first electronic component in the housing. The invention enables an electronic component in a housing with a space left between the housing to be potted with reduced formation of bubbles in the hardened potting material.

### BACKGROUND OF THE INVENTION

In the manufacture of electronic components, the components are often disposed in a housing. In addition, the components are often seated or sealed in the housing with a potting material, usually a curable or hardenable polymer material such as an epoxy. Electronic components may be potted in a housing for a variety of reasons, such as to seal the electronic component against the environment in which the component is anticipated to operate, to enhance the attachment of the component to the housing, or to enhance the overall structural integrity of the housed component unit.

In some circumstances, it may be desirable to completely fill a housing with potting material in order to fully encase the electronic component. Often times, however, it may be necessary that the housing is not completely filled with potting material. For example, the housing may contain electronic or other components in addition to the component desired to be potted that will be adversely affected by contact with the potting material. Alternatively, parts of the component being potted may be adversely affected by contact with the potting material, e.g., where the component being potted is an electronic circuit board is a printed circuit board having components mounted thereto that may be disturbed by shrinkage of the potting material during hardening or differences between the coefficient of thermal expansion between the potting material and the circuit board when exposed to heat during operation. In such cases where the housing is not completely filled with potting material, a gap or space is left between the potted component and the housing. Such a space or gap may provide the necessary isolation for certain components in the housing, but can result in bubbles being formed in the hardened potting material. These bubbles can cause unwanted porosity in the hardened potting material resulting in ineffective sealing or protection of the electronic components. Bubbles in the hardened potting material can also cause detrimental dimensional variations at the surface of the hardened potting material.

A typical prior art potted electronic component assembly is shown in FIG. 1, where printed circuit board 2 is disposed in housing 1. Electronic components 3 are disposed on the side of circuit board 2 away from potting material 5 in order to avoid adverse affects that could be caused by coming into contact with potting material 5. The disposition of electronic components 3 between the circuit board 2 and housing 1 necessitates spaces 4 between the circuit board and the housing. The air in spaces 4 forms bubbles during the curing or hardening of potting material 5, leading to bubbles 6 in the potting material, which can cause ineffective sealing or protection of the circuit board 2 and detrimental dimensional variations at the surface of potting material 5.

In order to avoid the problems caused by spaces or gaps between the potted component and the housing, it was attempted to fill the gaps with sand, e.g., silica sand of various sizes. However, it was difficult to get the sand to adequately fill into all of the gaps, requiring excessively long time vibration times in an attempt to get the sand to adequately fill into all of the gaps. Thus, there exists a need for potting an electronic component in a housing where a space is left between the housing and the potted component with reduced formation of bubbles in the hardened potting material.

### SUMMARY OF THE INVENTION

According to the present invention, there is provided in one embodiment a method of manufacturing an electronic component assembly, comprising the steps of:
(a) disposing a first electronic component in a housing such that there is at least one void space between the first electronic component and the housing;
(b) disposing non-conductive microspheres in the void space in a quantity sufficient to substantially fill the void space; and
(c) disposing a fluid potting material in the housing and hardening or curing the potting material so as to pot the first electronic component in the housing.

In another embodiment, there is provided an electronic component assembly comprising:
(a) a housing;
(b) a first electronic component disposed in the housing such that there is at least one space between the first electronic component and the housing, and the space is substantially filled with non-conductive microspheres; and
(c) a cured or hardened potting material that pots the first electronic component in the housing.

The invention enables an electronic component to be potted in a housing with a space left between the housing and the potted component, with reduced formation of bubbles in the hardened potting material.

These and other advantages and features will become more apparent from the following description taken in conjunction with the drawings.

### BRIEF DESCRIPTION OF THE DRAWINGS

The subject matter which is regarded as the invention is particularly pointed out and distinctly claimed in the claims at the conclusion of the specification. The foregoing and other features, and advantages of the invention are apparent from the following detailed description taken in conjunction with the accompanying drawings in which:

FIG. 1 represents a prior art potted electronic component.

FIG. 2 represents an electronic component disposed in a housing in accordance with the invention, prior to being potted.

FIG. 3 represents an electronic component disposed in a housing along with microspheres in accordance with the invention, prior to being potted.

FIG. 4 represents an electronic component disposed in a housing with microspheres disposed in the space between the component and the housing in accordance with the present invention, prior to being potted.

FIG. 5 represents a potted electronic component disposed in a housing with microspheres disposed in the space between the component and the housing in accordance with the present invention.

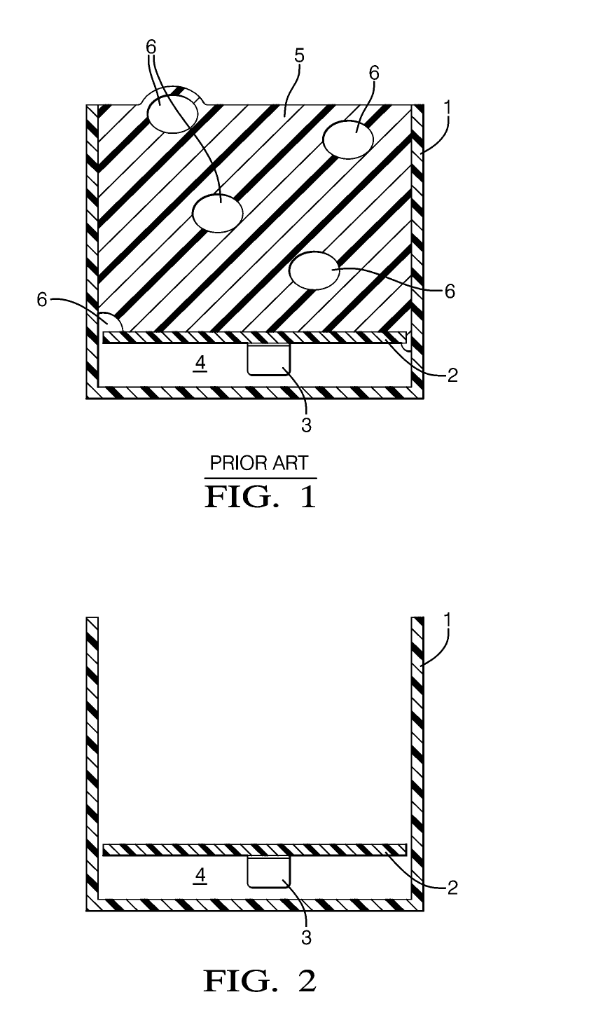

### DETAILED DESCRIPTION

Referring now to the Figures, where the invention will be described with reference to specific embodiments, without limiting same.

The method and electronic component assembly of the present invention is disclosed in an exemplary, non-limiting context of a printed circuit board disposed in an housing such as a cavity in the solenoid body of a pressure switch assembly in an automotive transmission, although the invention can be applied to virtually any potted electronic component in any housing.

Referring now to FIGS. 2 -5, the method and assembly of the invention is illustrated in stages. In FIG. 2, there is shown the first stage of assembly where printed circuit board 2 having electronic components 3 mounted thereon is disposed in housing 1 with electronic components 3 disposed between circuit board 2 and housing 1, thereby forming spaces 4 between circuit board 2 and housing 1. In a non-limiting exemplary embodiment, the circuit board 2 may be affixed to housing 1 to hold it in place, with a slight gap between the edge of circuit board 2 and the side walls of housing 1.

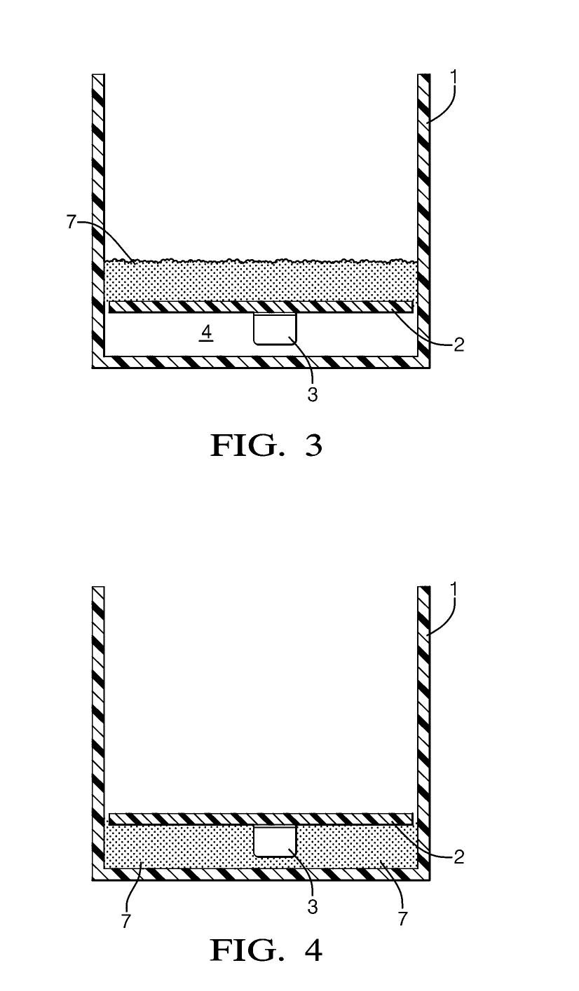

In FIG. 3, non-conductive microspheres 7 (also known as beads, e.g., glass beads, or microballoons) are disposed in the housing on top of printed circuit board 2 on the opposite side from electronic components 3. The micospheres may be of any non-conductive material that can withstand the curing conditions for the potting material and the environmental conditions to which the electronic device may be exposed. In one exemplary embodiment, the microspheres are glass, e.g., silica glass, or ceramic. Polymer materials may also be used to form the microspheres, e.g., polyethylene, polystyrene. In an exemplary embodiment of the invention, the particle size of the microspheres ranges from between 1 μm and 1000 μm. In another exemplary embodiment, the microspheres have particle size diameters ranging between 10 μm to 200 μm. In yet another exemplary embodiment, the microspheres have particle size diameters ranging between 20 μm to 80 μm. In a further exemplary embodiment, the particle size distribution of the microspheres has a mean particle size of 60 μm to 80 μm. Where the electronic component is an internal component for an automatic transmission of a motor vehicle, in an exemplary embodiment the microspheres are smaller than 50 μm, and in another exemplary embodiment have a mean particle size ranging between 25 μm and 45 μm.

Turning now to FIG. 4, non-conductive microspheres 7 are disposed in the spaces 4 between circuit board 2 and housing 1. This may be accomplished, for example, by subjecting the assembly of FIG. 3 to vibration sufficient to cause microspheres 7 to flow and settle into the spaces 4. In this exemplary embodiment, there is a gap between the edges of circuit board 2 and the side walls of housing 1 that is large enough for the microspheres 7 to flow through in order to reach the spaces 4. Also, in this embodiment, the particle size and density of the microspheres should be chosen so as to facilitate flow of the microspheres into the spaces 4. In an exemplary embodiment for this application, the microspheres made of solid material.

Alternatively, the assembly of FIG. 4 may be formed by disposing microspheres 7 into the area that will become spaces between the circuit board and the housing prior to disposing the circuit board into the housing. In this embodiment, care should be taken that the microspheres do not interfere with the proper fit and alignment of the circuit board into the housing. In one exemplary embodiment of this technique, the spaces are due to irregularities in the shape of the housing, such as recesses in the housing (not shown) instead of due to irregularities in the shape of a circuit board caused by electronic components mounted thereon.

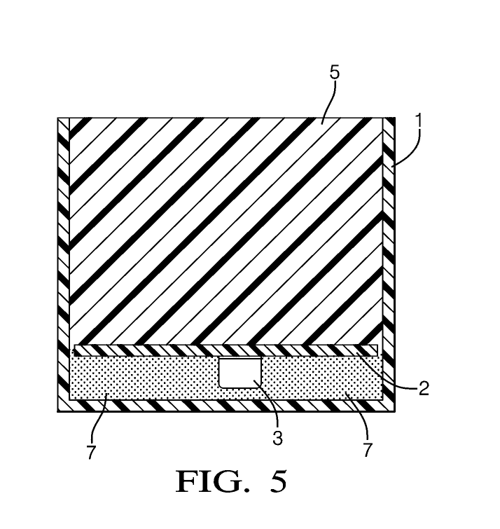

Turning now to FIG. 5, potting material 5 has sealed circuit board 2, having electronic component 3 mounted thereon, into housing 1. Spaces 4 were filled up by microspheres 7, thereby avoiding the formation of detrimental bubbles in the potting material 5 so that the cured or hardened potting material is substantially free of any porosity that would disrupt the seal of the encapsulated electronic component from fluid intrusion and/or has no distortions from a flat smooth surface greater than 0.3 mm. The potting material can be any of a number of materials well-known in the art for potting of electronic components. In an exemplary embodiment, the potting material is a one-part or two-part self-curing liquid polymer resin that solidifies after being poured into the housing 1, such as a one-part epoxy resin, a two-part epoxy resin system, or a two-part urethane resin, or a two-part urethane system. Silicones may also be used as well as siliconized epoxies and urethanes. Other materials, such as acrylics or thermoplastics are also known to be used as potting materials. In one exemplary embodiment, the potting material generates heat during an exothermic curing reaction. In another exemplary embodiment, heat is applied by an external source to aid in hardening or curing of the potting material. In either case, exemplary temperatures during hardening or curing can range from 120° C. to 170° C.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description.

Having thus described the invention, it is claimed:

1. A method of manufacturing an electronic component assembly, comprising the steps of:
(a) disposing a first electronic component in a housing such that there is at least one void space between the first electronic component and the housing;
(b) disposing non-conductive microspheres in said void space in a quantity sufficient to substantially fill said void space; and
(c) disposing a fluid potting material in said housing and hardening or curing said potting material so as to pot said first electronic component in said housing.

2. A method according to claim 1 wherein said microspheres are glass beads.

3. A method according to claim 1 wherein said microspheres are stable at temperatures of at least up to 150° C.

9. A method according to claim 1 further comprising the step of disposing a second electronic component in said housing between said housing and said first electronic component so as to provide said void space, either before or after step (a).

10. A method according to claim 6 wherein the step of disposing the second electronic component is performed before step (a).

11. A method according to claim 1 wherein a difference in shape profile between said first electronic component and said housing provides said void space.

12. A method according to claim 1 wherein steps (a), (b), and (c) are performed in order, and further comprising the step, after step (b) and before step (c), of vibrating the housing or the first electronic component or both the housing and the first electronic component so as to distribute the microspheres into said void space.

13. A method according to claim 7 wherein steps (a), (b), and (c) are performed in order, and further comprising the step, after step (b) and before step (c), of vibrating the housing or the first electronic component or both the housing and the first electronic component so as to distribute the microspheres into said void space.

14. A method according to claim 1 wherein said encapsulated electronic component assembly is a pressure switch assembly for motor vehicle electronic transmission control assembly.

17. A method according to claim 1 wherein said potting material is a curable epoxy.

18. A method according to claim 1 wherein said void space is substantially free of said potting material.

19. A method according to claim 1 wherein said hardening or curing step includes the generation of heat by or the application of heat to the potting material.

20. An electronic component assembly comprising:
(a) a housing;
(b) a first electronic component disposed in said housing such that there is at least one space between the first electronic component and the housing, said space substantially filled with non-conductive microspheres; and
(c) a cured or hardened potting material potting said first electronic component in said housing.

21. An electronic component assembly according to claim 20 wherein said microspheres are glass beads.

22. An electronic component assembly according to claim 20 wherein said microspheres have particle size diameters ranging between 1 μm to 1000 μm.

23. An encapsulated electronic component assembly according to claim 20 wherein said microspheres have particle size diameters ranging between 10 μm to 200 μm.

24. An electronic component assembly according to claim 20 wherein said microspheres have particle size diameters ranging between 20 μm to 80 μm.

25. An electronic component assembly according to claim 24 wherein said microspheres have a mean particle size diameter of between 25 μm and 45 μm.

26. An electronic component assembly according to claim 20 wherein said microspheres are smaller than 50 μm.

27. An electronic component according to claim 20 wherein said potting material is a curable epoxy.

28. An electronic component according to 20 wherein said void space is substantially free of said potting material.

29. An electronic component according to 20 wherein the cured or hardened potting material is substantially free of any porosity that would disrupt the seal of the encapsulated electronic component from fluid intrusion.

30. An electronic component according to 20 wherein the cured or hardened potting material has no distortions from a flat smooth surface greater than 0.3 mm.
